(19) United States
(12) Patent Application Publication
(10) Pub. No.: US 2007/0052091 A1
(43) Pub. Date: Mar. 8, 2007

(54) Electronic device and method of manufacturing same

(75) Inventors: Johannus Wilhelmus Weekamp, EINDHOVEN (NL); Marc Andre De Samber, Eindhoven (NL); Eric Cornelis Egbertus Van Grunsven, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 10/539,314

(22) PCT Filed: Dec. 15, 2003
(86) PCT No.: PCT/IB03/06028

§ 371 Date: Jun. 15, 2005

(30) Foreign Application Priority Data
Dec. 20, 2002 (EP) 02080665.9

(51) Int. Cl. H01L 23/34; H01L 21/00

(52) U.S. Cl. 257/724; 438/107; 257/E23.079

(57) ABSTRACT

The device of the invention comprises a semiconductor element, a first connection element, a first patterned electrically conductive layer and a second patterned electrically conductive layer. The device is further provided with an encapsulation that encapsulates all except the first conductive layer, which is part of the substrate. The device can be suitably made in that the second conductive layer is provided, in pre-patterned form, with a permeable isolating layer as a foil.

The invention relates to a method of manufacturing an electronic device, comprising the steps of:
providing elements, including a semiconductor element and a first connection element, on a first side of a substrate with a first conductive layer, thereby bringing at least two of the elements, one of which is the first connection element, and corresponding conductors in the first layer into electric contact;
applying a second conductive layer on either side of the elements, thereby bringing at least the two elements and the second layer into electric contact;
applying a passivating material, which forms an encapsulation of the elements; and
separating the assembly of substrate, encapsulation and second conductive layer, thereby forming the electronic device.

The invention also relates to an electronic device with a first side and a second, opposite side that is provided with a semiconductor element having a first and a second connection region that is situated between a first and a second layer of electrically conductive material on, respectively, the first and the second side, which layers are electrically interconnected via at least a first connection element, conductors being defined in accordance with a desired pattern in said layers, the semiconductor element being electrically connected with at least a number of said conductors via the connecting regions, said device being provided, on the first side, with contact faces for external contacting, said contact faces being electroconductively connected with at least part of the conductors in the first layer, said elements being at least substantially encapsulated by an encapsulation of a passivating material.

The invention further relates to a foil.

Such a method and such a device are described in the non-prepublished application IB02/02305 (PHNL0110398). In said application, the semiconductor element is a transistor or a slightly more complex element that is provided, on the first side, with a number of connection regions and, on the second side, with one connection region, which are used to form an electrically and/or thermally conductive connection using a conductive adhesive, i.e. a heat sink or a contact. The device comprising the connection element has the advantage that external contacting can take place on a single side, in this case the first side, although the connection regions are located on opposite sides. The connection element is, for example, a body of silicon or copper.

In the known method, the substrate and the second conductive layer each take the form of conductive plates. The elements are provided on the second conductive plate and attached by means of an electroconductive adhesive. Said elements are provided with bumps on the first side. Subsequently, the first conductive plate is provided on said bumps. Next, the isolating material, in this case a so-termed underfill material, is provided from the side edges of the device and also cured. To establish a conductive connection between the bumps and the first conductive plate, preferably, a temperature step is carried out. The first plate is subsequently patterned by means of a mask.

The provision of the isolating material from the side edges proves to be unfavorable in practice. If a large number of devices are simultaneously manufactured, it takes comparatively long for the isolating material to encapsulate all elements. In addition, there is a substantial risk that the elements and the bumps are not completely encapsulated, which leads to mechanical stresses and failure. Moreover, the material choice is limited to the group formed by the underfill materials.

Therefore, it is a first object of the invention to provide a method of the type described in the opening paragraph, by means of which the isolating material can be readily provided, and which nonetheless enables the device to be built up from the substrate and all contact faces for external contacting to be situated on one side. This first object is achieved in that:

the second layer is patterned and comprises interconnected connection conductors and conductors;

the second layer is provided as part of a foil, thereby bringing at least the two elements and the connection conductors into electric contact, and

the passivating material is provided from the second side of the semiconductor element through the foil.

In the method in accordance with the invention, a foil is used instead of a second conductive layer in the form of a plate. Said foil comprises the second conductive layer in an already patterned form, but by virtue of the connecting function of further foil parts, this second conductive layer can be provided as a whole. Said further foil parts include, for example, an electrically isolating layer, which may or may not be detachable or patterned. By virtue of this “permeable” foil, the isolating material can be provided from the second side of the semiconductor element. Thus, a much larger surface is available for providing the isolating material, which results in a much faster process and a smaller risk of incomplete encapsulation.

It is an advantage of the method in accordance with the invention that the second conductive layer is not present in the sawing paths. The presence of conductive material, in particular copper, in the sawing paths complicates the sawing process and adversely affects the service life of the saws used. Therefore, it is advantageous to remove the copper photolithographically. A lithographic step after the assembly process is not desirable either, however, owing to practical conditions in assembly plants. In the method in accordance with the invention, this problem is substantially absent.

A further advantage resides in that the second conductive layer may comprise additional patterns for increased functionality. Coils, couplers, shields and microstrips, for example, may be provided.

It is advantageous in particular that the second conductive layer may comprise many more patterns. This enables modules to be manufactured comprising a large number of elements, without all elements being interconnected via the second conductive layer. An additional advantage of the method resides in that a large variety of isolating materials for the encapsulation can be used. Examples include glass epoxides, acrylates, polyimides but also sol-gel materials that can be cured to glass. The provision of the isolating material through the foil can be carried out using various application techniques. Examples include injection molding, spraying, spin or web coating, etc.

In a first embodiment in accordance with the invention, the foil comprises a detachable layer which is removed after the foil has been provided on the second side of the semiconductor element. The foil can be removed because the second patterned layer is supported by the elements, and in particular the connecting means on the second side thereof. Well-known connecting means include metal bumps and electroconductive adhesive. It is an advantage of the embodiment that the second patterned layer can in principle be used as a substrate for further elements. These elements are provided, preferably, prior to the application of the isolating material. The thickness of the second conductive layer can be adapted to the mass of the further elements. Preferably, however, this thickness is limited and lies in the range of approximately 100 nm to 50 μm. Examples of elements are semiconductor elements, sensors, heat sinks, passive elements etc.

In a second embodiment, the foil comprises a patterned, electrically isolating layer, the foil being provided in such a manner that the second patterned layer faces the elements. The isolating layer is preferably embedded in the isolating material. It is therefore desired that the isolating layer bonds sufficiently well to the isolating material. In addition, the isolating layer must be capable of withstanding the heat treatments carried out to cure the isolating material of the encapsulation and to re-melt solder and/or metal. Furthermore, the isolating material must not have a negative effect on the operation of the device. In practice, satisfactory results have been obtained by using dry solder resist, which is commercially available from, inter alia, Norton, and structurable materials such as polyimide and benzocyclobutene.

In a third embodiment, the foil comprises an electrically isolating gauze, the foil being provided in such a manner that the second patterned layer faces the elements. It has been found that the strength of such a gauze is sufficient for keeping together the second conductive layer. At the same time, by virtue of the open structure of the gauze, there are no negative effects on the mechanical and thermal stability of the encapsulation or on the operation of the device. Gauze, made for example of a nylon material or of glass fibers, has in principle sufficient thermal stability to withstand said thermal treatments. However, if the gauze were to melt during such a thermal treatment, then this can be readily coped with by the encapsulation. At that point in time the mechanical function of the gauze has become redundant anyway. The gauze can of course be provided on a detachable layer for a simplified treatment.

In principle, the choice of the substrate is completely free and depends only on the specific application and the conditions during assembly. In this connection, use is preferably made of a substrate in which the connection conductors are already defined in the first layer. Such a substrate has the advantage that after the provision of the isolating material, a photolithographic step, as applied in the method described hereinabove, can be dispensed with. A first example of such a substrate is, for example, a lead frame. This still has the drawback that the carrier function of the substrate and the connection function are not separated, so that to separate the assembly of substrate and encapsulation the metal lead frame must be cut through. A second example of such a substrate is a foil with the first conductive layer, which foil is detachable. A third example of such a substrate is a carrier layer with the first conductive layer.

It is particularly favorable if the substrate comprises a sacrificial layer which is at least partly removed after the passivating material has been provided. The sacrificial layer is essentially a temporary carrier layer. The advantage of a sacrificial layer as compared to a foil is its dimensional stability and mechanical stability. At the same time, the first conductive layer may be absent at the location of the sawing paths. The removal can take place by means of etching, polishing or by exposure to UV radiation.

The use of a sacrificial layer offers two additional possibilities. Firstly, by selective removal of the sacrificial layer prior to the provision of the isolating material, the first conductive layer can be anchored in the encapsulation. This leads to a better adhesion between substrate and encapsulation. In particular, the electroconductive layer is connected, on the side facing away from the first side, with a layer which is patterned essentially in accordance with the same pattern as the conductive layer. The patterns of this intermediate layer or sub-layer of the sacrificial layer have a smaller diameter in a plane parallel to the layer, resulting in said anchoring.

A second advantage of the sacrificial layer is that it enables contact faces for external contacting to be readily formed on a second side of the substrate facing away from the first side of the substrate. In particular, vias through an isolating carrier layer can be dispensed with.

Particularly favorable results are obtained with a sacrificial layer of Al and a conductive layer of Cu, as described in the non-prepublished application EP 02076425.4 (PHNL 020318), and with a three-layer or multilayer concept of Cu—Al—Cu, as described in the non-prepublished applications EP 02076426.2 (PHNL 020327) and EP 02079544.9 (PHNL 021100).

Furthermore, it is favorable to provide the elements on the first side with bumps and on the second side with an electroconductive adhesive. An extremely good encapsulation of the elements can be obtained, in this case, by applying a deliquescent layer, such as an acrylate layer, between the substrate and the elements, such as is known per se from the non-prepublished application EP 02077228.1 (PHNL 020471).

In a further modification, the passivating material also encapsulates the second patterned layer, and the substrate comprises, on a second side facing away from the first side, contact faces for external contacting. An important advantage of the device in accordance with the invention resides in that all contact faces for external contacting are situated on a single side. As a result, if use is made of bumps, in a ball grid or land grid array, or otherwise, for external contacting, the contact faces may be present in the substrate or in or on the second conductive layer. By defining the contact faces in the substrate, the second conductive layer can be entirely encapsulated. In this manner, a device is obtained having outwardly projecting conducting parts only on one side, without the need of providing an additional layer. Furthermore, the number of patterns in the second conductive layer is minimized by positioning the contact faces in the substrate. This enhances the ease of providing the isolating material.

It is a second object of the invention to provide an electronic device of the type described in the opening paragraph, which electronic device can be manufactured by means of the method in accordance with the invention and is provided with internal conductors for connecting connection regions on the second side with the contact faces.

This object is achieved in that:

the second electroconductive layer is patterned and provided with a first connection conductor for the second connection region of the semiconductor element and a second connection conductor for the connection element, which connection conductors are interconnected; and

as well as the elements, the encapsulation also substantially encapsulates the second conductive layer.

As a result of said encapsulation of the second conductive layer, the desired device is obtained.

For the semiconductor element use can be made of all kinds of elements. Essentially, at least three classes of elements can be distinguished; the first class of elements includes vertical semiconductor elements with connection regions on either side of the element. These elements are, inter alia, diodes and bipolar transistors. By means of the connection element, which may be a conductive body or ball as well as a semiconductor element and a passive element, the conductors are fed back to the contact faces.

The second class of semiconductor elements includes the semiconductor elements wherein the connection with the second layer serves for heat dissipation and/or grounding. Examples thereof are, in particular, amplifiers and ICs. The method is suitable, in particular, for the manufacture of a HVQFN package for an IC. In this case, the semiconductor element is placed with the rear side, i.e. the semiconductor body, on a conductor defined as a heat sink in the first layer. The connection elements in this case are bodies or preferably metal or solder bumps. Subsequently, the connection regions on the semiconductor element are connected with the conductors in the second layer. Via the connection elements, these are fed back to the contact faces on the first side of the device. It is just by the use of this foil that this becomes possible. After all, the foil has the advantageous effect that the second layer can be embodied so as to be thin, i.e. of the order of 0.1 to 10 μm. By virtue thereof, the resolution of the pattern can be increased to a level required for an integrated circuit having tens of connection regions.

A comparable device is known per se from U.S. Pat. No. 6,300,161. In said document, the second layer is present however on a separate carrier layer, also referred to as interposer. This carrier layer is not encapsulated by the passivating material. An advantage of the device in accordance with the invention as compared to the known device is primarily the compactness, particularly in terms of thickness, and secondly the ease of assembly. A further advantage as compared to conventional HVQFN assembly techniques is that the separation process does not require sawing through the HVQFN lead frame. If use is made of a sacrificial layer as part of the substrate, a further advantage can be achieved, i.e. the individual devices are definitively separated only in a very late stage of the manufacture, for example after testing. Said separating may take place by removing the sacrificial layer, for example by means of etching in a suitable bath, after the encapsulation has already been separated.

The third class of semiconductor elements includes the semiconductor elements that are connected only with the first layer. In addition, in the second layer and/or as connection elements, elements are present that provide additional functionality. In particular, the semiconductor element used herein is an integrated circuit. The elements providing additional functionality are, for example, protection diodes, decoupling capacitors, and, defined in the second layer, coils, resistors or also sensors.

The connection element is preferably a body of silicon or copper. Alternatively, it may be a metal or solder ball, in particular if the semiconductor element has a small thickness. The connection element may also itself be a semiconductor element or a passive component however.

The device may be obtained in a favorable manner by means of the method according to the invention, and may advantageously have one or more of the special features as described with regard to the substrate, the patterns in the second conductive layer, etc.

It is a third object to provide a foil for use in the invention. This object is achieved by a foil comprising a patterned, electrically isolating carrier layer and a patterned electroconductive layer. In the conductive layer, connection conductors, interconnect connections etc. are provided in accordance with a desired pattern. The carrier layer is, for example, a gauze or a solder resist. In particular, the carrier layer is made of a material capable of withstanding thermal treatments in the range of 200-300° C., since it can be integrated in the device. The patterns in the carrier layer comprise apertures through which passivating material can flow. Particularly if an injection molding process is used, the apertures are preferably equal to or larger than the distance between the foil and the mold. A customary dimension in this case is approximately 300 μm. The foil may be provided with a detachable layer.

These and other aspects of the invention are apparent from and will be elucidated with reference to the embodiment(s) described hereinafter.

In the drawings:

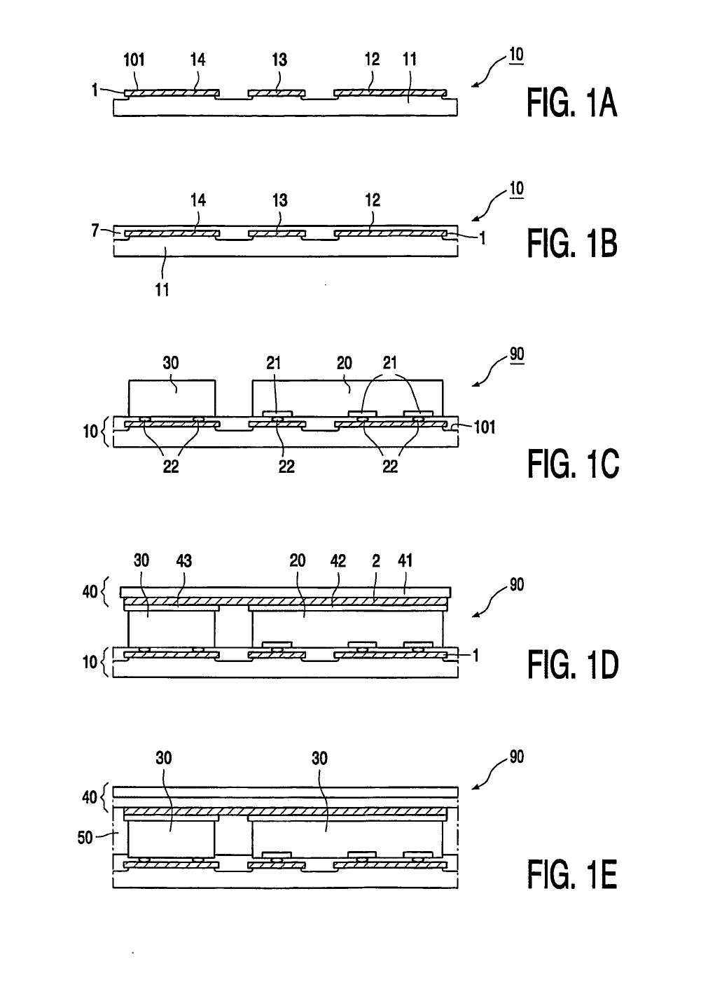

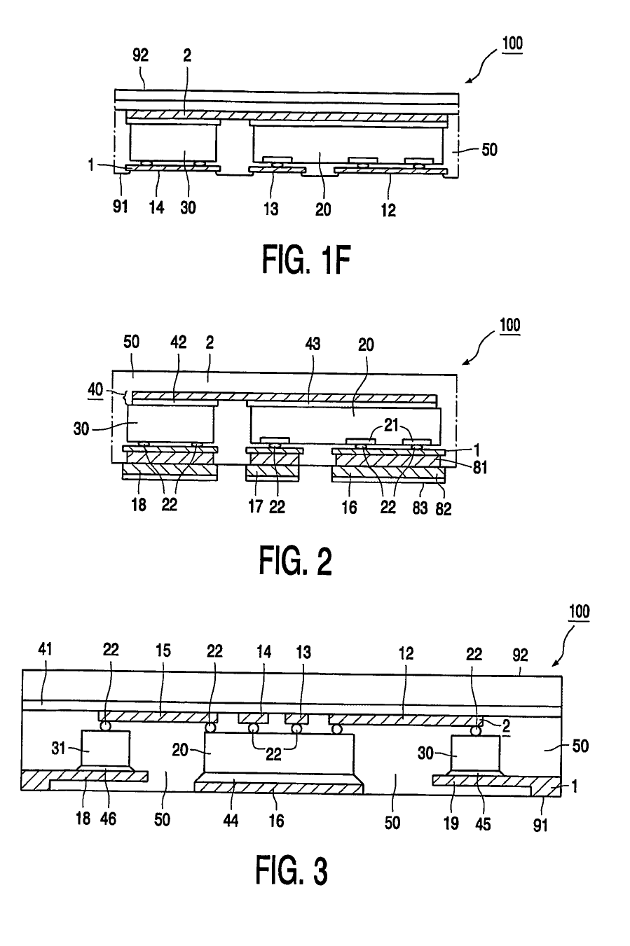

FIGS. 1A-F are diagrammatic sectional views of the device in a number of stages in the method;

FIG. 2 is a cross-sectional view of a second embodiment of the device;

FIG. 3 is a cross-sectional view of a third embodiment of the device;

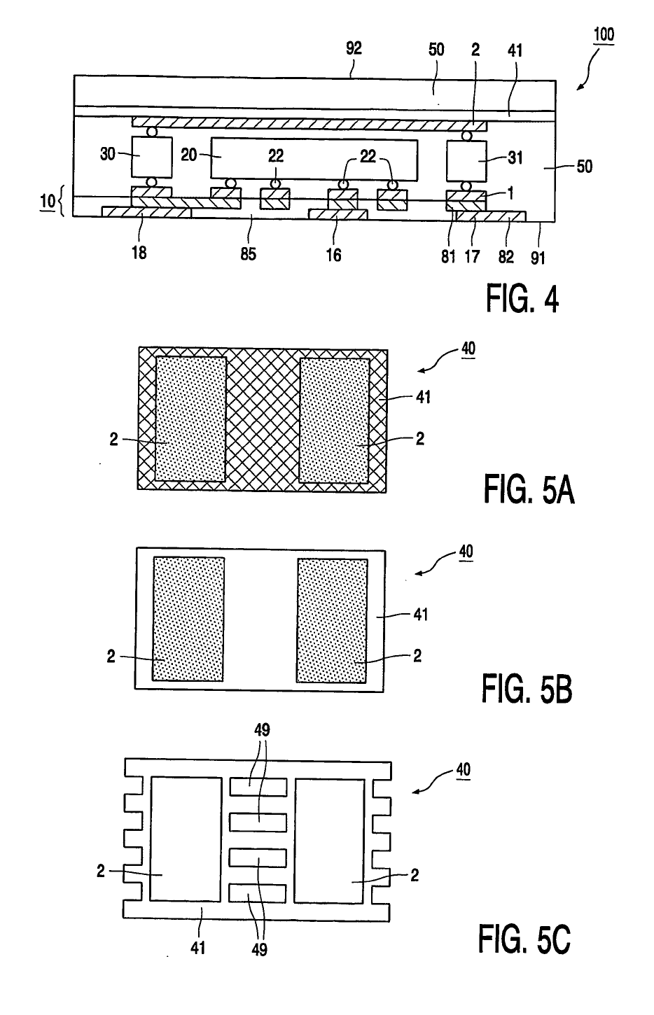

FIG. 4 is a cross-sectional view of a fourth embodiment of the device; and

FIGS. 5A-C are plan views of three embodiments of the foil for use in the method.

The figures are not drawn to scale and some dimensions are exaggerated for clarity. Corresponding regions or parts bear the same reference numerals whenever possible.

FIGS. 1A-F are diagrammatic, cross-sectional views of a number of stages in the manufacture of the electronic device by means of the method in accordance with the invention.

FIG. 1A shows a substrate 10 with a sacrificial layer 11 and a first layer 1 of an electroconductive material. The electroconductive material used here is copper and has a thickness of preferably 1 to 10 μm, while the sacrificial layer 11 comprises, in this case, Al or an alloy of Al. The first layer 1 is provided with an adhesion layer for solder, for example of Sn. Connection conductors 12, 13, 14 are defined in the first layer 1. If necessary, also other conductors, not shown, are present. The first layer 1 can be patterned, inter alia, by means of etching, for example by applying a photomask and using ferrichloride as an etchant. After patterning of the first layer 1, in this example, an etch step has been carried out, which is not essential however. In this etch step, the sacrificial layer is etched such that the conductors 12, 13, 14 in the first layer 1 are partly underetched. A suitable etchant is sodium hydroxide solution.

FIG. 1B shows the substrate 10 after a continuous, electrically isolating layer 7 has been provided on a first side 101 thereof. Said isolating layer 7 here is a 25 μm thick layer of a synthetic resin comprising an acrylate foil. Said acrylate foil is exposed to a small pressure and moderate heat to attach it to the first patterned layer 1 that is provided with tin layers.

FIG. 1C shows the provisional, not yet separated device 90 after a semiconductor element 20 and a first connection element 30 have been provided on the first side 101 of the substrate 10. The semiconductor element 20 here is a bipolar transistor, while the first connection element 30 is a body of copper. The elements 20, 30 are provided with metal balls 22 which, in this case, are made of Au. Said metal balls 22 are situated on connection regions 21 on the semiconductor element, which are conventionally defined in the semiconductor element. By a thermal treatment during or after the provision of the elements, for example up to approximately 100° C., the isolating layer of acrylate is softened and the metal balls 22 sink to the surface of the substrate 10, after which the metal connection is established by further heating to, for example, 265° C. As will be understood by those skilled in the art, this temperature depends on the solder material used. If necessary, use can be made of pressure means, not shown in the drawing. Also heating means, which are positioned at the lower side of the substrate 10, are not shown in the drawing.

FIG. 1D shows the device 90 after the foil 40 has been applied to the elements 20, 30. Said foil 40 comprises a second patterned layer 2 having a thickness of, preferably, 30-60 μm, and, in this example, a patterned isolating layer 41 of a dry-film solder resist. The foil is attached to the elements 20, 30 by means of adhesive layers 42, 43 of an electrically conductive adhesive, for example an epoxy filled with Ag, as is known to those skilled in the art.

FIG. 1E shows the device 90 after isolating material has been provided so as to form the encapsulation 50. The isolating material is provided, in this case, by means of injection molding in a mold (not shown) through the isolating layer 41 of the foil 40. For the isolating material use is made, for example, of an epoxy that is cured by means of a thermal treatment. The encapsulation 50 comprises the acrylate layer 7 and encapsulates not only the elements 20, 30 but also the second patterned layer 2 and the isolating layer 41.

FIG. 1F shows the device 100 after, in succession, the sacrificial layer 11 has been removed and the device has been separated from the neighboring devices, not shown. The contact faces 12, 13, 14, which in this case are identical to the connection conductors and form part of the first layer 1, thus appear at the surface on the first side 91 of the device 100, while the second layer 2 on the second side 92 of the device is embedded in the encapsulation 50.

FIG. 2 is a cross-sectional view of a second embodiment of the device 100. In this embodiment, a foil with a detachable carrier layer is used. As a result, the foil 40 in the device 100 consists only of the second patterned layer 2 and adhesive layers 42, 43. A further difference in comparison with the device shown in FIG. 1 relates to the substrate 10. This substrate comprises, in this example, a five-layer stack, the uppermost adhesion layer not being shown. The other layers are the first patterned layer 1, an intermediate layer 81, in this case of an Al alloy, an under-layer 82 of Cu and an adhesion layer for solder 83, for example of Ti. Of course, other materials may also be chosen. As the patterns in the intermediate layer 81 have a smaller diameter than those in the first layer 1, the first layer 1 is mechanically anchored in the encapsulation 50, i.e. in this case the part formed by the acrylate layer 7. This substrate 10 is provided after the intermediate layer 81 has been partly removed. The under-layer 82 is partly removed after the provision of the encapsulation 50, the adhesion layer for solder 83 being used as an etch mask.

FIG. 3 is a cross-sectional view of a third embodiment of the device 100 in accordance with the invention. In this example, the first layer 1 is patterned to form conductors 16, 18, 19 in the form of a HVQFN lead frame (High-Voltage Quad Flat Non-leaded). Apart from a semiconductor element 20, which in this case is an integrated circuit, a first and a second connection element 30, 31 are present thereon. These elements are placed on the first layer 1 by means of conductive adhesive layers 44, 45, 46. For this purpose, the first layer 1 may be supported, during the manufacture, by a sacrificial layer (not shown), which is removed at a later stage; such a sacrificial layer is not necessary however. The first layer 1 comprises, in this example, Cu. The elements 20, 30, 31 are placed on the first layer 1 and were already provided with metal balls 22. On the metal balls there is a foil with a patterned isolating layer 41 and the second layer 2, said second layer 2 facing the metal balls 22, and a metal connection being formed. For this purpose, the second layer 2 is preferably provided with a suitable adhesion layer. In the second layer, connection conductors 12, 13, 14, 15 are defined, with conductors 12, 15 providing for a conductive connection between the relevant contacts at the semiconductor element 20 and the connection elements 30, 31. Also the conductors 13, 14 form interconnect connections to further connection elements, which are not shown. In practice, a larger number of contacts than indicated is probable, in particular in the case of complex integrated circuits. In order to accommodate this number of conductors in the second layer 2, said layer 2 is preferably embodied so as to be a thin layer having a thickness of 5 μm and a resolution of less than 5 μm. The elements 20, 30, 31 are encapsulated by the encapsulation 50, the contact faces 16, 17, 18, forming part in this case of the first layer 1, being situated on the first side 91 of the device 100. On the second side 92, the encapsulation extends to above the isolating layer 41. However, this is not necessary.

FIG. 4 is a cross-sectional view of a fourth embodiment of the device 100. This comprises a semiconductor element 20, here an integrated circuit, which is connected by metal balls 22 to the first layer 1. In addition, the device 100 comprises a first and a second connection element 30, 31, the first one of which is a diode and the second one is a conductive body. The second layer 2 here is an interconnect layer interconnecting the first and the second connection element 30, 31. The connection conductors in the first layer 1 are further connected, via the intermediate layer 81, with contact faces 16, 17, 18 in the under-layer 82. The substrate 10 further comprises isolating material 85.

FIGS. 5A-C are plan views of three embodiments of the foil 40. The foil comprises a carrier layer 41 which is made, at least in the embodiments shown in FIGS. 5A and 5C, of an electrically isolating material. The foil 40 further comprises the second patterned layer 2 wherein a desired pattern is defined. In the embodiments shown here, said layers (?) constitute two conductors by means of which elements 20, 30, as shown in FIGS. 1 and 2, can be interconnected. FIG. 5A shows the embodiment wherein a gauze, for example of nylon, is used as the carrier layer 41. FIG. 5B shows the embodiment wherein a detachable layer is applied as the carrier layer. For this purpose use may be suitably be made of a polymer layer on which a desirably adhering adhesive layer is applied. FIG. 5C shows the embodiment wherein a patterned layer is used as the carrier layer 41. This carrier layer is provided with apertures 49 which are obtained using a known, preferably inexpensive, patterning technique. The foil shown in FIG. 5C can be advantageously manufactured by using the solder resist also as the etch mask and removing certain patterns under said etch mask by underetching. As a result, it is required however that the conductive layer has a thickness of several tens of microns, for example 30-60 micrometer. If other techniques and a separate etch mask are used, it is of course possible to produce conductive layers having a smaller thickness and hence a higher resolution, for example a track width and pitch between the tracks of 5-10 micron.

1. A method of manufacturing an electronic device comprising the steps of:
providing a substrate having a first layer of an electroconductive material, in which layer conductors are or will be defined in accordance with a desired pattern;
providing a foil having a second patterned layer of electroconductive material, in which layer conductors are defined in accordance with a desired pattern;
providing elements, including a semiconductor element and a first connection element, on a first side of the substrate, thereby bringing at least two of the said elements, one of which is the first connection element, and corresponding conductors in the first layer into electric contact;
providing the foil on either side of the elements, thereby establishing electric contact between at least the two elements and the corresponding conductors in the second layer;
providing a passivating material from the second side of the semiconductor element through the foil, which passivating material forms an encapsulation of the elements; and
separating the assembly of substrate, encapsulation and second conductive layer, thereby forming the electronic device.

2. A method as claimed in claim 1, characterized in that the foil comprises a detachable layer which is removed after the foil has been provided on the second side of the semiconductor element.

3. A method as claimed in claim 1, characterized in that the foil comprises a patterned, electrically isolating layer, the foil being provided in such a manner that the second patterned layer faces the elements.

4. A method as claimed in claim 1, characterized in that the foil comprises an electrically isolating gauze, the foil being provided in such a manner that the second patterned layer faces the elements.

5. A method as claimed in claim 1, characterized in that a substrate is used in which the connection conductors are already defined in the first layer.

6. A method as claimed in claim 5, characterized in that the substrate comprises a sacrificial layer which is at least partly removed after the provision of the passivating material.

7. A method as claimed in claim 1 or 5, characterized in that the passivating material also encapsulates the second patterned layer, and that the substrate has contact faces for external contacting which are situated on a second side facing away from the first side.

8. An electronic device with a first side and a second, opposite side that is provided with a semiconductor element having a first and a second connection region that is situated between a first and a second patterned layer of electrically conductive material on, respectively, the first and the second side, which patterned layers are electrically interconnected via at least a first connection element, conductors being defined in accordance with desired patterns in said layers, and the semiconductor element being electrically connected with conductors in at least one of said layers by the connecting regions, said device being provided, on the first side, with contact faces for external contacting, said contact faces being electroconductively connected with at least a part of the conductors in the first patterned layer, said elements and said second patterned layer being at least substantially encapsulated by an encapsulation of passivating material.

9. An electronic device as claimed in claim 8, characterized in that the second conductive layer is provided, on the side facing away from the elements, with a patterned isolating layer.

10. An electronic device as claimed in claim 8, characterized in that the second conductive layer is provided, on the side facing away from the elements, with a gauze of isolating material.

11. A foil comprising a patterned, electrically isolating carrier layer and a patterned, electrically conductive layer, which patterns of the layers are different.

12. A foil as claimed in claim 11, characterized in that the isolating carrier layer is a gauze.
